(19) United States
(12) Patent Application Publication
(10) Pub. No.: US 2023/0258415 A1
(43) Pub. Date: Aug. 17, 2023

(54) LIQUID-INFUSED SURFACES FOR INCREASING HEAT TRANSFER

(71) Applicants: The Trustees of Princeton University, Princeton, NJ (US); Board of Regents, The University of Texas System, Austin, TX (US); KTH Royal Institute of Technology, Stockholm (SE)

(72) Inventors: Marcus Hultmark, Princeton, NJ (US); Shervin Bagheri, Stockholm (SE); Johan Sundin, Stockholm (SE); Stefano Leonardi, Austin, TX (US); Umberto Ciri, Austin, TX (US)

(73) Assignees: The Trustees of Princeton University, Princeton, NJ (US); Board of Regents, The University of Texas System, Austin, TX (US); KTH Royal Institute of Technology, Stockholm (SE)

(21) Appl. No.: 18/111,216

(22) Filed: Feb. 17, 2023

Related U.S. Application Data
(60) Provisional application No. 63/311,185, filed on Feb. 17, 2022.

(51) Int. Cl. F28F 3/02

(52) U.S. Cl. CPC F28F 3/025; F28F 2255/20; F28F 2260/00

(57) ABSTRACT

Disclosed are systems and techniques for increasing heat transfer from a substrate to a working fluid. The systems may include a substrate comprising a plurality of grooves or cavities on at least one external surface. The system may also include an infusing liquid filling at least a majority of the plurality of grooves. The system may also include a working fluid configured to flow parallel to the external surface.

### CROSS-REFERENCE TO RELATED APPLICATIONS

The present application claims priority to U.S. provisional patent application 63/311,185, filed Feb. 17, 2022, which is incorporated by reference herein in its entirety.

### TECHNICAL FIELD

The present application is drawn to heat transfer surfaces, and specifically, to techniques for improving heat transfer through use of specifically engineered surfaces.

### BACKGROUND

This section is intended to introduce the reader to various aspects of art, which may be related to various aspects of the present invention that are described and/or claimed below. This discussion is believed to be helpful in providing the reader with background information to facilitate a better understanding of the various aspects of the present invention. Accordingly, it should be understood that these statements are to be read in this light, and not as admissions of prior art.

The simultaneous increase of heat transfer and reduction of drag in laminar and turbulent fluid flows has turned out to be a considerable challenge. Such technology could lower the power input required for driving the flow in heat exchangers, microprocessors, and other thermal systems. A common technique to increase heat transfer in applications is to use rough or modified walls. While surface roughness, grooves, blades, ridges, and corrugations increase the surface heat flux, they also increase the momentum transport, resulting in increased drag. Enhancement of heat transfer in pipes, channels, and ducts can also be achieved by miniaturization since this increases the surface-to-volume ratio. Effectively, more liquid is then in contact with the surface for a given volume flow rate. However, reduced dimensions also lead to increased wall friction so that the required pressure drop (and pumping power) increases.

### BRIEF SUMMARY

Various deficiencies in the prior art are addressed below by the disclosed compositions of matter and techniques.

In various aspects, a system for increasing heat transfer from a substrate to a working fluid may be provided. The system may include a substrate comprising a plurality of grooves (which may be, e.g., micro- and/or nano-scale grooves) or cavities on at least one external surface. The system may include an infusing liquid filling at least a majority of the plurality of grooves. The system may include a working fluid configured to flow parallel to the external surface.

In some embodiments, each of the plurality of grooves may be a rectangular groove. In some embodiments, each of the plurality of grooves may be oriented in a first direction on the at least one external surface. In some embodiments, the working fluid may be configured to flow in a second direction, the second direction being perpendicular to the first direction. In some embodiments, each of the plurality of grooves are oriented in a seemingly random fashion on the at least one external surface. In some embodiments, the substrate may be comprised of a polymer, metal, dielectric, or semiconductor. In some embodiments, the infusing liquid may be comprised of a hydrocarbon or a liquid metal. In some embodiments, the hydrocarbon may be an alkane. In some embodiments, the alkane may have a carbon chain of the alkane is 6-18 carbons in length. In some embodiments, the working fluid may comprise water. In some embodiment, the system may also include a processor or circuitry in thermal communication with the infusing liquid.

In various aspects, a method for providing increased heat transfer with minimal increase in frictional losses may be provided. The method may include flowing a working fluid parallel to an external surface of a substrate, the external surface comprising a plurality of grooves (which may be, e.g., micro- and/or nano-scale grooves) or cavities and an infusing liquid filling at least a majority of the plurality of grooves or cavities, such that the working fluid thermally communicates with the infusing liquid and the plurality of grooves. In some embodiments, the plurality of grooves consists of micro and/or nano-scale grooves.

In some embodiments, each of the plurality of grooves may be a rectangular groove. In some embodiments, each of the plurality of grooves may be oriented in a first direction on the at least one external surface. In some embodiments, the working fluid may be configured to flow in a second direction, the second direction being perpendicular to the first direction. In some embodiments, each of the plurality of grooves are oriented in a seemingly random fashion on the at least one external surface. In some embodiments, the substrate may be comprised of a polymer, semiconductor, dielectric, or a metal. In some embodiments, the infusing liquid may be comprised of a hydrocarbon or a liquid metal. In some embodiments, the hydrocarbon may be an alkane. In some embodiments, the alkane may have a carbon chain of the alkane is 6-18 carbons in length. In some embodiments, the working fluid may comprise water. In some embodiments, the method may include controlling flow of the working fluid based on a measured temperature.

### BRIEF DESCRIPTION OF DRAWINGS

The accompanying drawings, which are incorporated in and constitute a part of this specification, illustrate embodiments of the present invention and, together with a general description of the invention given above, and the detailed description of the embodiments given below, serve to explain the principles of the present invention.

FIG. 1 is a cross-sectional view of an embodiment of a system.

FIGS. 2A-2E are cross-sectional views of individual grooves.

FIG. 3 is an isometric view of an embodiment of a surface.

FIG. 4 is a 2D view of a random series of grooves.

FIG. 5 is a flowchart of a method.

FIG. 6A is an illustration showing contributions to the heat flux in a system.

FIG. 6B is a schematic illustration of an example interface unit cell for a liquid infused surface.

FIG. 7A is a graph showing the change in q/q⁰ because of varying κₛ for three different viscosity ratios and Pr_{∞}=1, 10, and 100 at Re_{∞}=100.

FIG. 7B is a graph showing different contributions to q for κₛ/κᵢ=0.5, 1, and 2 at Re_{∞}=100, μᵢ/μ_{∞}=1, and Pr_{∞}=10.

FIG. 8A-8C are graphs showing the relative contribution to the heat flux from convection, as a function of Re_{∞} (8A), Pe_{∞} (8B), and (c) Peᵢ (8C). In 8A results for μᵢ/μ_{∞}=1 are shown, whereas 8B and 8C contain results for μᵢ/μ_{∞}=0.1, 1, and 10; Prandtl numbers are Pr_{∞}=0.1, 1, 10, and 100.

FIG. 9A is a graph showing the Reynolds number of the flow in the grooves, Reᵢ, expressed as a function of the external flow Reynolds number, Re_{∞}, for p/k=2 and three different viscosity ratios (μᵢ/μ_{∞}=0.1, 1, and 10). The relation is approximately linear for low Reynolds numbers.

FIG. 9B is a graph showing the derived Stokes limit slip lengths over the pitch, b/p, for three different p/k and groove width w=p−k.

FIG. 10A is a graph showing a comparison of convective heat flux for LIS in laminar flow and turbulent flow for [symbol] \tilde{v}\tilde{T} [symbol] \hat{ }+.

FIG. 10B is a graph showing a comparison of q_{conv,d}/q from the turbulent simulations and eq. (4.3).

FIG. 11 is an illustration showing the flow domain used in example turbulent simulations. The mean flow is in the positive x-direction. The upper wall is smooth. Transverse grooves have been added on the bottom, on top of a slab of the same height, k. They correspond to a solid fraction ϕₛ=¼. The external fluid is not shown.

FIG. 12 is a graph showing a comparison of eq. (5.3), assuming E=0 (solid, dashed, or dotted-and-dashed lines) and ϵ=2.3·10⁻³ (dotted lines, corresponding to Pr_{∞}=2), to simulation results shown with circles for the three values of Pro.

FIG. 13A is a graph showing the root-mean-squared wall-normal velocity for turbulent flow over LIS (solid line for vᵣₘₛ⁺; dashed line for dispersive component v_{rms,d}⁺; dotted-and-dashed line for random component v_{rms,r}⁺; and dotted line for a smooth wall reference).

FIG. 13B is a graph showing drag reduction of the disclosed LIS as a function of the slip length in nominal wall units (circle), compared to an ideal relation (solid line).

It should be understood that the appended drawings are not necessarily to scale, presenting a somewhat simplified representation of various features illustrative of the basic principles of the invention. The specific design features of the sequence of operations as disclosed herein, including, for example, specific dimensions, orientations, locations, and shapes of various illustrated components, will be determined in part by the particular intended application and use environment. Certain features of the illustrated embodiments have been enlarged or distorted relative to others to facilitate visualization and clear understanding. In particular, thin features may be thickened, for example, for clarity or illustration.

### DETAILED DESCRIPTION

The following description and drawings merely illustrate the principles of the invention. It will thus be appreciated that those skilled in the art will be able to devise various arrangements that, although not explicitly described or shown herein, embody the principles of the invention and are included within its scope. Furthermore, all examples recited herein are principally intended expressly to be only for illustrative purposes to aid the reader in understanding the principles of the invention and the concepts contributed by the inventor(s) to furthering the art and are to be construed as being without limitation to such specifically recited examples and conditions. Additionally, the term, “or,” as used herein, refers to a non-exclusive or, unless otherwise indicated (e.g., “or else” or “or in the alternative”). Also, the various embodiments described herein are not necessarily mutually exclusive, as some embodiments can be combined with one or more other embodiments to form new embodiments.

The numerous innovative teachings of the present application will be described with particular reference to the presently preferred exemplary embodiments. However, it should be understood that this class of embodiments provides only a few examples of the many advantageous uses of the innovative teachings herein. In general, statements made in the specification of the present application do not necessarily limit any of the various claimed inventions. Moreover, some statements may apply to some inventive features but not to others. Those skilled in the art and informed by the teachings herein will realize that the invention is also applicable to various other technical areas or embodiments.

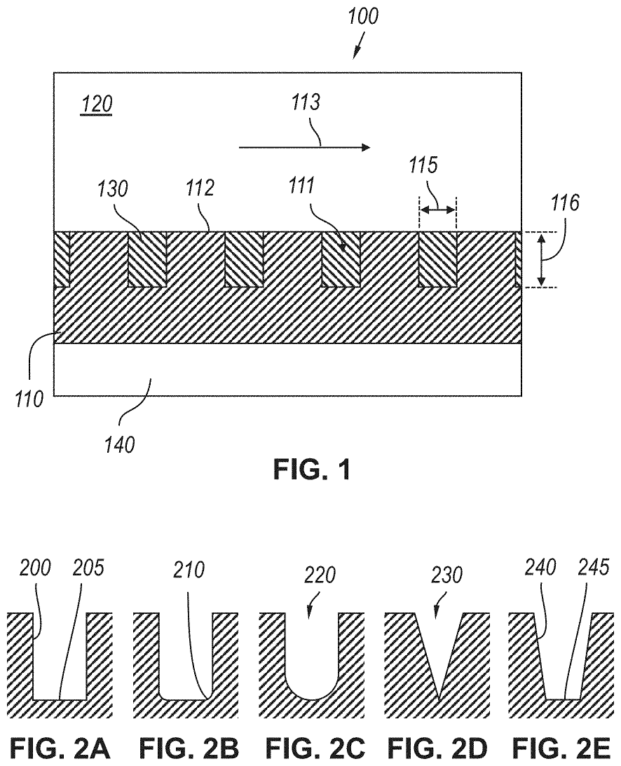

In some embodiments, a system for increasing heat transfer from a substrate to a working fluid may be provided. Referring to FIG. 1, the system 100 may include a substrate 110. The substrate may include a plurality of grooves 111 or cavities on at least one external surface 112.

In some embodiments, the plurality of grooves may consist of micro- and/or nano-scale grooves. As used herein, the term “micro-scale” with respect to a feature means that at least one dimension of the feature has a length-scale of less than one millimeter but no less than one micrometer. As used herein, the term “nano-scale” with respect to a feature means that at least one dimension of the feature has a length-scale of less than one micrometer. Each groove may have a width 115 and depth 116. In some embodiments, both the width and depth are micro-scale. In some embodiments, both the width and depth are nano-scale. In some embodiments, one of the width or depth is micro-scale, and the other is nano-scale. In some embodiments, each groove has the same width and depth. In some embodiments, the width and/or depth of at least one groove is different from at least one other groove. In some embodiments, the width and depth of each groove is constant across the entire length of the groove. In some embodiments, the width and/or depth of each groove may vary across at least a portion of the length of the groove.

Each groove may have a cross-sectional shape that may be the same or different from other grooves. In some embodiments, each groove has the same cross-sectional shape. In some embodiments, the cross-sectional shape of at least one groove is different from the cross-sectional shape of at least one other groove.

The grooves may have any cross-sectional shape. Referring to FIG. 2A, in some embodiments, a groove may have a rectangular cross-section (e.g., a “rectangular groove”). The two sidewalls 200 of the groove are parallel and vertical (and may be, e.g., perpendicular to the most external surface 112). The bottom 205 of the groove is flat and perpendicular to the sidewalls (and may be, e.g., parallel to the most external surface 112).

In some embodiments, the edges (“corners” as seen in a cross-sectional view) where the bottom connects to the sidewalls may form 900 angles. However, referring to FIG. 2B, in some embodiments, a groove may have, e.g., rounded corners 210.

In some embodiments, a groove may have no flat bottom. For example, referring to FIG. 2C, in some embodiments, a groove may have a “U” shape 220, with generally parallel vertical sidewalls. Referring to FIG. 2D, in some embodiments, a groove may have a “V” shape 230, with non-parallel sidewalls.

Referring to FIG. 2E, in some embodiments, a groove may have a pyramidal shape, with non-parallel sidewalls 240 and a flat bottom 245.

The grooves may be formed to have various orientations.

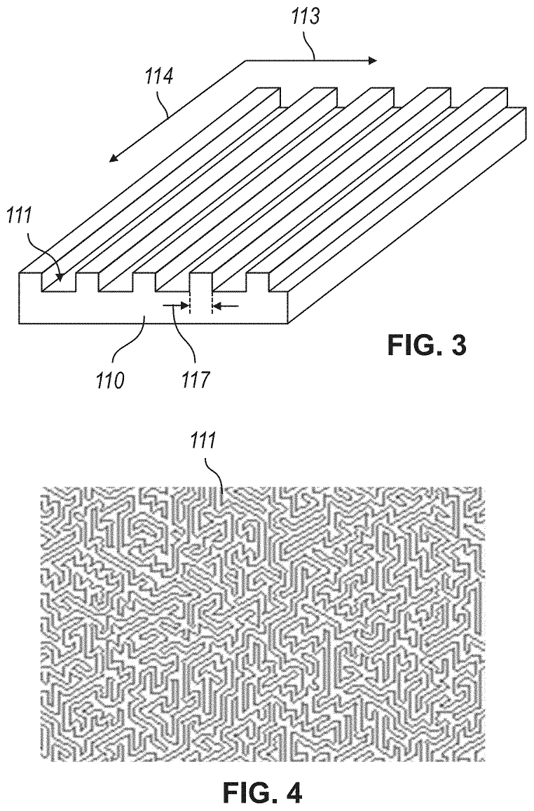

Referring to FIG. 3, in some embodiments, every groove 111 may be oriented in one direction 114 (for example, the grooves may be oriented to generally move from a left side of the substrate to a right side of the substrate). In some embodiments, every groove may be parallel to every other groove. In some embodiments, a minimum distance 117 between every groove and an adjacent groove is identical. In some embodiments, the minimum distance between at least one groove and an adjacent groove is different from the minimum distance between a different groove and its adjacent groove. In some embodiments, the minimum distance between one groove and an adjacent groove may be constant for the entire length of the groove. In some embodiments, the minimum distance between one groove and an adjacent groove may vary for at least a portion of the entire length of the groove.

In some embodiments, the grooves may be straight. In some embodiments, the grooves may include one or more curves. Referring to FIG. 4, in some embodiments, the grooves 111 may be disposed in a seemingly random fashion. For example, in some embodiments, the grooves may form a random or pseudo-random pattern. As used herein, the term “pseudo-random” refers to something generated or obtained using a finite, nonrandom computational process. In other words, pseudo-random values refer a set of values that is statistically random but is derived from a known starting point. Pseudorandom sequences may, therefore, exhibit statistical randomness while being generated by an entirely deterministic causal process.

The substrate is comprised of a rigid or semi-rigid material. As used herein, the term “semi-rigid” describes a shape or configuration of a material that allows limited deformation under moderate stresses and strains but exhibits a restoring force that effects an inherent resiliency, i.e., a tendency to return to its original shape or configuration when the stresses or strains are removed.

In some embodiments, the substrate may be a polymer, semiconductor (such as silicon), a dielectric (such as silicon dioxide or silicon nitrite), or a metal (such as stainless steel, copper, aluminum). In some embodiments, the polymer may be a thermally conductive polymer. As used herein, the term “thermally conductive polymer,” means a polymer having a thermal conductivity, measured in watts/meter-Kelvin (W/m-K) of at least 1.0, measured according to ASTM E1461 and F433. In some embodiments, the polymers may have a thermal conductivity of at least 1.5, at least 2.0, at least 2.5, or at least 3.0 W/m-K. Non-limiting examples of thermally conductive polymers include thermally conductive polypropylene, thermally conductive nylon, and thermally conductive polycarbonate. In some embodiments, the polymer may include sufficient metal or ceramic fillers to achieve a desired level of thermal conductivity.

Referring to FIG. 1, the system may include a working fluid 120 that is configured to flow in a direction 113 that is parallel to the external surface 112.

In some embodiments, the working fluid may be configured to flow in a direction 113 that is perpendicular to the direction 114 the grooves are oriented.

In some embodiments, the working fluid may be any appropriate heat transfer fluid. In some embodiments, the heat transfer fluid may comprise water. In some embodiments, the working fluid may be an aqueous composition The system according to any one of claim 1, wherein the working fluid comprises water. In some embodiments, the working fluid may comprise ethylene glycol. In some embodiments, the working fluid may comprise an ethylene glycol-water mixture.

Referring to FIG. 1, the system may include an infusing liquid 130 that is configured to fill at least a majority of the plurality of grooves. That is, more than 50% of the plurality of grooves must have an infusing liquid disposed within the groove, completely filling the groove, but not overflowing outside the groove. The working fluid should be able to contact the most external surface 112 of the substrate around each groove.

In some embodiments, the infusing liquid may include a hydrocarbon (such as an alkane, such as an alkane having a carbon chain that is 6-18 carbons in length), or a liquid metal.

In some embodiments, the infusing liquid may be a nanofluid. As used herein, the term nanofluid refers to a fluid that contains particles having a size in nanometer scale (e.g., 100 nm or less), such as nanodiamond particles, graphene-oxide, or the composite formed of those particles. The nanofluid may also contain a fluid, particularly a liquid fluid within which the particles are dispersed.

In various embodiments, the design of the grooves or cavities, in conjunction with the infusing liquid, must be configured to satisfy two criteria.

First, the velocity inside the grooves should be such that the Peclet number within it is above 1. This implies that the velocity must be greater than the thermal diffusivity of the liquid in the cavity divided by the length scale of the cavity.

Second, the thermal conductivity of the solid (e.g., substrate) should be on the order of (or less) than the thermal conductivity of the liquid in the cavity. That is, in some embodiments, the thermal conductivity of the solid may be less than the thermal conductivity of the infusing liquid.

Referring to FIG. 1, in some embodiments, the system may have a semiconductor 140, sensor, or circuitry operably coupled to the substrate 110, such that the semiconductor (such as a processor), sensor, or circuitry is in thermal communication with the substrate. As used herein, the term “thermal communication” refers to the ability to transfer thermal energy from one body to another or from one body to a fluid medium.

In various embodiments, a method for providing increased heat transfer with minimal increase in frictional losses may be provided. Referring to FIG. 5, in some embodiments, the method 500 may include providing 510 a substrate as disclosed herein, having an external surface, where the external surface comprises a plurality of grooves or cavities, and where and an infusing liquid as disclosed herein fills at least a majority of the plurality of grooves or cavities. The method may include flowing 520 a working fluid parallel to the external surface of a substrate, such that the working fluid thermally communicates with the infusing liquid and the plurality of grooves.

In some embodiments, the method may include adjusting/controlling 530 a direction or velocity of flow of the working fluid based on a measured temperature (such as a temperature of the working fluid).

### Example

Both heat transfer increase and drag reduction can be achieved with complex surfaces having more degrees of freedom to tune the surface-flow interaction, such as liquid-infused surfaces (LIS). The infused liquid creates a dynamic interface that induces a slipping effect on the external flow while affecting wall-normal velocity fluctuations. The careful design of texture topology, liquid viscosity, thermal conductivity, and surface tension enables the precise tuning of transport processes.

Several efforts have used superhydrophobic surfaces (SHS) to reduce friction while maintaining the benefits of reduced system size. Similar effects could be accomplished with LIS. An analytical model of heat transfer in pipes with SHS or LIS, taking the reduced friction into account, was recently developed. Indeed, reducing the pipe radius increased the advantage of using SHS and LIS. Some LIS and SHS models have been developed to attempt to increase heat transfer and decreased drag in direct numerical simulations of turbulent flow. Out of the investigated surface configurations, this occurred only for SHS with longitudinal grooves, dynamic interfaces, and gas-liquid thermal conductivity ratio one. The solid structures were also assumed to have a constant temperature. This thermal conductivity ratio and the isothermal textures are hard to realize in actual conditions, however.

If the thermal conductivity of the solid texture is similar to a contiguous liquid, the heat flux in neither phase is trivial. These solid-liquid combinations are not rare in applications. For example, water has a thermal conductivity that is higher than the polymer polydimethylsiloxane (PDMS). LIS made from such materials can be expected to have a very different heat flux compared to LIS with isothermal surface textures. For metal solids, liquid metals may be used as infused liquids. There has recently been an increase in liquid gallium alloys with low toxicity in stretchable electronics. The thermal conductivity of gallium is comparable to that of steel.

The differences between the fluid properties can be expressed through the viscosity ratio, μᵢ/μ_{∞}, density ratio, ρᵢ/ρ_{∞}, specific heat capacity ratio, c_{p,i}/c_{p,∞}, and thermal conductivity ratio, κᵢ/κ_{∞}, where the subscripts i and ∞ refer to the infused and external fluids, respectively. For example, others have previously used a heptane-water system (among others) with μᵢ/μ_{∞}=0.43, κᵢ/κ_{∞}=0.21, and c_{p,i}/c_{p,∞}=0.53. An overview of some properties is given in Table 1, below.

TABLE 1
Overview of various properties for some fluids and solids.

| Material | κ [W/(mK)] | μ [mPas] | ρ [kg/m³] | cₚ [kJ/(kgK)] |
|---|---|---|---|---|
| Water | 0.60 | 1.0 | 1000 | 4.18 |
| Polydimethylsiloxane | 0.16 | — | — | — |
| (PDMS) | | | | |
| Gallium (liquid) | 29 | 1.97 | 6080 | 0.35 |
| Steel | 45 | — | — | — |
| Hexane | 0.120 | 0.33 | 655 | 2.23 |
| Heptane | 0.124 | 0.43 | 684 | 2.20 |
| Dodecane | 0.135 | 1.4 | 750 | 2.19 |

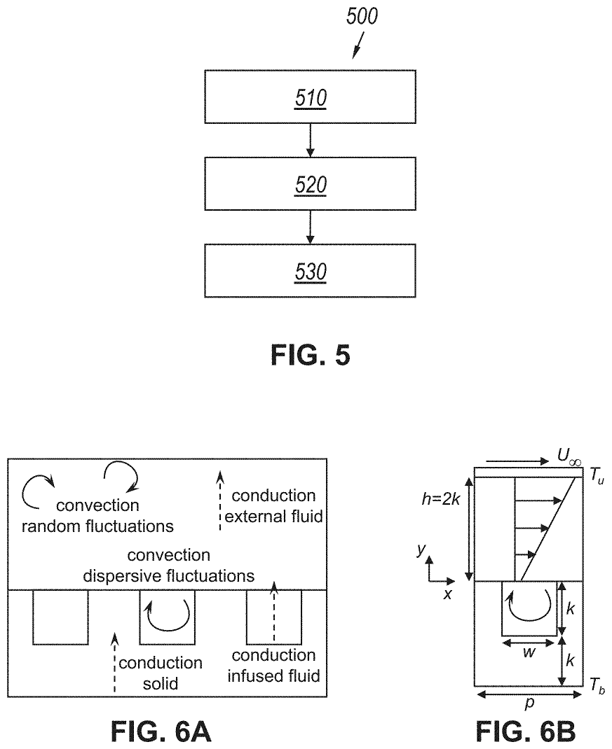

Using liquid and solid properties similar to those of existing materials, this example illustrates how convection in the texture of LIS with transverse grooves can increase the surface heat flux, considering both laminar and turbulent flows. This mode of heat transfer has either been neglected or has not been evaluated previously. The study was performed by numerically solving the equations for the velocity and the temperature fields. The heat transfer mechanisms that are considered in this example are shown schematically in FIG. 6A. The convection by the mean flow of the working fluid was not considered, and the problem was simplified to the heat transport between two external boundaries of different temperatures.

Governing Equations

The momentum, continuity, and energy equations for an incompressible system are considered,

$$ρ \frac{\partial u}{\partial t} + ρ ( u \cdot ∇ ) u = - ∇ P + ∇ \cdot μ ( ∇ u + {( ∇ u )}^{T} ) = 0 \qquad ( 2.1 )$$

$$∇ \cdot u = 0 \qquad ( 2.2 )$$

$$ρ {c}_{p} \frac{\partial T}{\partial t} + ρ {c}_{p} u \cdot ∇ T = ∇ \cdot κ ∇ T$$

where u is the fluid velocity, P is the pressure, T is the temperature, μ is the fluid viscosity, and κ is the thermal conductivity. The streamwise coordinate is x, the wall-normal y, with y=0 at the surface, and the spanwise z. Eqs. (2.1) and (2.2) are valid in the domains occupied the external fluid and the infused (internal) liquid. In the region occupied by the solid, only eq. (2.3) is valid and u=0. For simplicity and clarity, it is assumed that densities, specific heat capacities, and thermal conductivities in the fluids are equal, i.e., ρ=ρᵢρ_{∞}, c=c_{p,i}=c_{p,∞}, and κᵢ=κ_{∞}.

The velocity satisfies the no-slip and impermeability conditions at solid boundaries. Across liquid-liquid interfaces, the velocity and the shear are continuous. In some examples, interface deformation can be neglected, equivalent to imposing an infinite surface tension; consequently, the wall-normal velocity component, v, is zero at the interface. The temperature and the heat flux are continuous at solid boundaries and interfaces. Also, the temperature is a passive scalar so that the momentum equation is solved independently of the energy equation.

The heat flux of the surface, q, can be decomposed into different contributions using the Fukagata, Iwamoto, and Kasagi (FIK) identity of the energy equation (see Fukagata et al. 2005). In this decomposition, a channel of height h and grooves of depth k with a solid slab of the same thickness beneath are considered (see FIG. 6B).

The second term of Eq. (2.3) gives rise to two convection terms, and the third term gives rise to three conduction terms. In total, the expression for q is

$$q = - \frac{{κ}_{∞}}{h + 2 k} {\int }_{0}^{h} 〈 \frac{\partial T}{\partial y} 〉 dy - \frac{{κ}_{s}}{h + 2 k} {\int }_{- 2 k}^{0} 〈 \frac{\partial T}{\partial y} {χ}_{s} 〉 d y - \frac{{κ}_{i}}{h + 2 k} {\int }_{- 2 k}^{0} 〈 \frac{\partial T}{\partial y} ( 1 - {χ}_{s} ) 〉 dy + \frac{ρ {c}_{p}}{h + 2 k} {\int }_{- k}^{h} 〈 {v}^{′} {T}^{′} 〉 dy + \frac{ρ {c}_{p}}{h + 2 k} {\int }_{- k}^{h} 〈 \tilde{v} \tilde{T} 〉 dy = {q}_{c o n d , ∞} + {q}_{cond , s} + {q}_{c o n d , i} + {q}_{conv , r} + {q}_{c o n v , d} \qquad ( 2.4 )$$

where χₛ is an indicator function equal to 1 in the solid and 0 elsewhere. The operator [symbol] [symbol] denotes the average in time and the streamwise and spanwise directions. The convective flux, [symbol] vT [symbol] is separated into a dispersive and a random component, [symbol] \tilde{v}\tilde{T} [symbol] and [symbol] v′T′ [symbol] , respectively. The first three terms on the last line of Eq. (2.4) describe conduction in the external liquid, the solid, and the infused liquid, respectively. The following two terms correspond to convection from random (turbulent) fluctuations and dispersive (or roughness coherent) fluctuations in the vicinity of the surface, respectively. Each of these terms has its counterpart before the equality sign in the same order. Their physical interpretations are illustrated in FIG. 6A. It is mainly the recirculation in the grooves that gives rise to [symbol] PT), which results in q_{conv,d}.

At every wall-normal location, q needs to be the same since there is no heat source inside the fluids or the solid. However, the sizes of the different terms would change with the domain height, as they are averaged over the complete domain, seen from the normalization with h+2k.

The laminar flow problem was solved in an interface unit cell, illustrated in FIG. 6B. These simulations were performed using the finite element solver FreeFem++. The height of the channel was h=2k, and the total domain height was 4k. At the upper boundary, constant shear stress and no normal stress was imposed. In the streamwise direction, periodic boundary conditions were imposed. Constant temperatures Tᵤ and T_{b} were applied at the upper and the bottom boundaries, respectively. A Reynolds number and a Péclet number based on the external flow quantities were defined as Re_{∞}=ρU_{∞}h/μ_{∞} and Pe_{∞}=ρcₚU_{∞}h/κ_{∞}, respectively, where U_{∞} is the streamwise velocity at the top boundary. The corresponding Prandtl number is Pr_{∞}=Pe_{∞}/Re_{∞}.

Heat Flux for Varying Solid Conductivity.

In laminar flow, there are no random fluctuations that transport heat. It follows that in the decomposition of the heat flux, q_{conv,r}=0. Eq. (2.4) reduces to

q=q_{cond,∞}+q_{cond,s}+q_{cond,j}+q_{conv,d} (3.1)

Smooth wall heat flux is used as a reference for the LIS simulations. If the surface of the laminar flow is smooth, two additional simplifications can be made. Since there is no spatially varying texture, the dispersive convection is zero. Neither is there infused liquid conducting heat. The heat flux only depends on the conduction in the solid and the external fluid and can be evaluated to

$${q}^{0} = \frac{{T}_{b} - {T}_{u}}{\frac{2 k}{{κ}_{s}} + \frac{h}{{κ}_{∞}}} \qquad ( 3.2 )$$

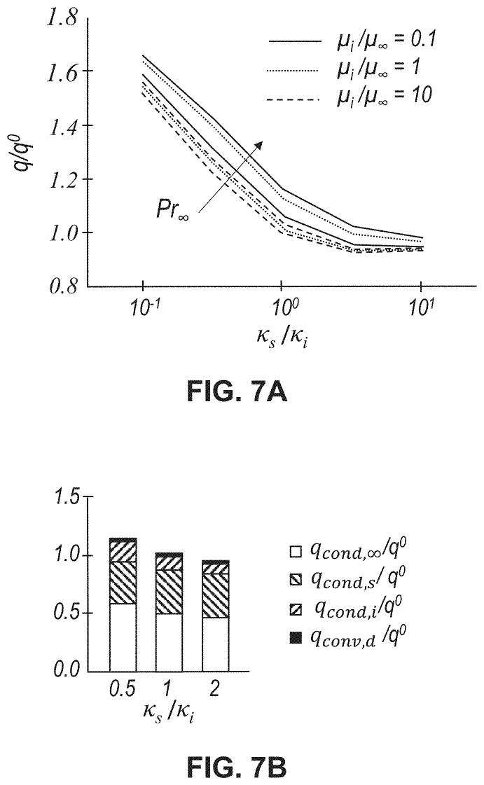

Notice that q also depends on κₛ, meaning that the reference heat flux changes with κₛ. In FIG. 7A, q/q⁰ is shown for varying solid conductivity ratios, κₛ/κᵢ. The applied shear stress corresponds to Re_{∞}=100 (neglecting the slight increase in U_{∞} due to the finite slip velocity). Three values of the Prandtl number, Pr_{∞}=1, 10, and 100, and three viscosity ratios, μᵢ/μ_{∞}=0.1, 1, and 10 were considered. For comparison, if the external fluid is water, Pr_{∞}=7, and the range of viscosity ratios covers all liquids of Table 1. The pitch was p=2k, and the groove width w=k. When κₛ/κᵢ=1, there is an increase in q/q⁰ from unity because of convection. For smaller κₛ/κᵢ, the average thermal conductivity of the surface is higher than for the solid alone, resulting in an even more pronounced increase in q/q⁰. However, when κₛ/κᵢ is increased above unity, there is eventually a decrease in the surface heat flux. At about κₛ/κᵢ=3, the simulations result in q/q⁰<1, except for the highest Pr_{∞} and the smallest viscosity ratio. It is thus necessary that κₛ≲κᵢ to have an increase in the heat flux. The different terms of eq. (3.1) are illustrated in FIG. 7B for Pr_{∞}=10, μᵢ/μ_{∞}=1, and κₛ/κᵢ=0.5, 1, and 2. For κₛ κᵢ=0.5, q/q⁰ would be greater than unity even without convection, whereas for κₛ/κᵢ=2, the convection cannot compensate for the cutout of the solid that is the groove. However, for κₛ/κᵢ=1, it is the convection that increases q/q⁰ above unity. Contour maps of the temperature fields of these three cases can be produced, together with streamlines. The streamlines indicate similarity between LIS and d-type roughness, with the external flow inhibited to penetrate the texture. This behaviour is enforced by the interface and therefore also holds for larger values of w/k. The contour levels of the temperature field have less spacing in the region of higher conductivity. They are also distorted in and around the grooves due to the convection of the vortex. The convection decreases the temperature on the left side of the cavity and increases it on the right side.

The heat fluxes through the different groove walls and the interface were computed. For κₛ/κᵢ=1, heat is transferred into the groove through the bottom wall and the right wall, while heat is transferred out of the groove through the interface and the left wall. Through the interface, the heat flux was q_{I}/q=1.071, i.e., slightly more than the average heat flux of the surface. The heat fluxes through the left, right and bottom walls were q_{L}/q=0.160, q_{R}/q=0.209, and q_{B}/q=1.021, respectively (imbalance |qₑᵣᵣ|/q=1.6·10⁻³). The increase of heat flux through the bottom wall, q_{B}>q, and sides, q_{R}, q_{L}>0 is due to the convection of the cavity vortex. This convection is quantified by q_{conv,d} and provides a net positive contribution to the total heat transfer of the surface (see FIG. 6B).

Properties of the Dispersive Convection

As disclosed herein, it is illustrated how the heat flux depends on κₛ/κᵢ. This section now focuses on the dependency on the fluid and flow properties expressed through Pr_{∞} and Re_{∞}. Since q_{conv,d} makes q/q⁰ increase above unity when the thermal conductivities are similar, the discussion is limited to κₛ/κᵢ=1. The heat then diffuses at the same rate in the solid as in the liquid, and the sum of the conduction terms can be simplified, leading to

$$q = [ {q}_{c o n d , ∞} + {q}_{c ond , s} + {q}_{cond , i} ] + {q}_{c onv , d} = [ \frac{{κ}_{∞}}{h + 2 k} ( {T}_{b} - {T}_{u} ) ] + \frac{ρ {c}_{p}}{h + 2 k} {\int }_{- 2 k}^{h} 〈 \tilde{v} \tilde{T} 〉 d y \qquad ( 4.1 )$$

The sum of the conduction terms is denoted g_{cond} and corresponds to q⁰ (eq. 3.2).

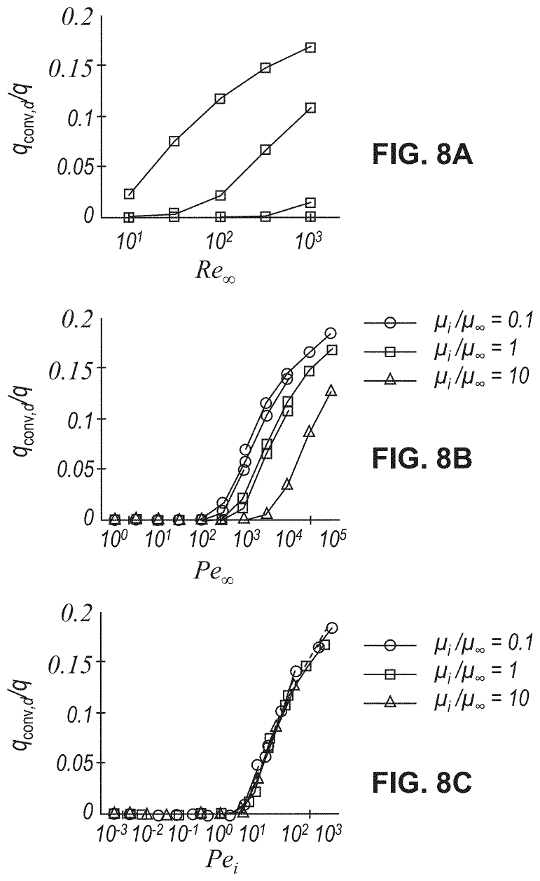

The relative contribution from convection to the total heat flux, q_{conv,d}/q, is shown in FIG. 8A as a function of Rem. These results were obtained for μᵢμ_{∞}=1 and Pr_{∞}=0.1, 1, 10, and 100, each curve corresponding to a specific Prandtl number. For a constant Rem, q_{conv,d}/q increases with Pr_{∞}, as is indicated in FIG. 7A. If q_{conv,d}/q instead is expressed as a function of Pe_{∞}=Re_{∞}Pr_{∞}, the curves collapse, as shown in FIG. 8B. Using the independent variable Pe_{∞}, the variations of q_{conv,d}/q with Pr_{∞} are minor. In this figure, the results for μᵢ/μ_{∞}=0.1 and μᵢ/μ_{∞}=10 are also included, however. For a specific Pe_{∞}, there is a dependency of q_{conv,d}/q on the viscosity ratio. Even if Re_{∞} and Pr_{∞} are constant, the magnitude of the flow inside the groove changes with viscosity ratio, and thereby the dispersive convection. Therefore, one needs to define Reynolds and Péclet numbers that are characteristic of the flow at the surface.

A representative velocity of the flow in the grooves is the mean velocity at the interface. If it is averaged over the whole surface, it equals the slip velocity, Uₛ, which is [symbol] u [symbol] at y=0, where u is the streamwise velocity component. Using Uₛ and k as velocity and length scales, respectively, Reynolds and Péclet numbers are defined as

$$R {e}_{i} = \frac{ρ {U}_{s} k}{{μ}_{i}} and {Pe}_{i} = \frac{ρ {c}_{p} {U}_{s} k}{{κ}_{i}} \qquad ( 4.2 )$$

together with a Prandtl number Prᵢ=Pe₁/Reᵢ. Curves for different viscosity ratios collapse if q_{conv,d}/q is expressed as a function of Peᵢ, as shown in FIG. 8C. For about Peᵢ>1, there is a noticeable increase in q_{conv,d}/q. At Peᵢ=10, q_{conv,d}/q is greater than 1%. The simulation results in FIG. 8C are well approximated by a logarithmic function for 10¹<Peᵢ<10³. This set of Peᵢ is the vital interval in practice, as it results in significant increases in heat transfer while still being attainable. The logarithmic function shown in the figure (dashed line) is

$$\frac{{q}_{conv , d}}{q} = \frac{k}{h + 2 k} 0.11 ln ( P {e}_{i} - 7.6 ) \qquad ( 4.3 )$$

found by fitting the data. This relationship is different from the power-laws used for the similar problem of a lid-driven cavity. Here, the logarithmic expression gives a better fit. For comparison, the root-mean-squared error of the logarithmic expression was 0.0054, whereas, for a power-law fit of α(Peᵢ^{β}−1), it was 0.011, where α=0.73 and β=0.11 (with −1 added assuming q_{conv,d}→0 when Peᵢ→1).

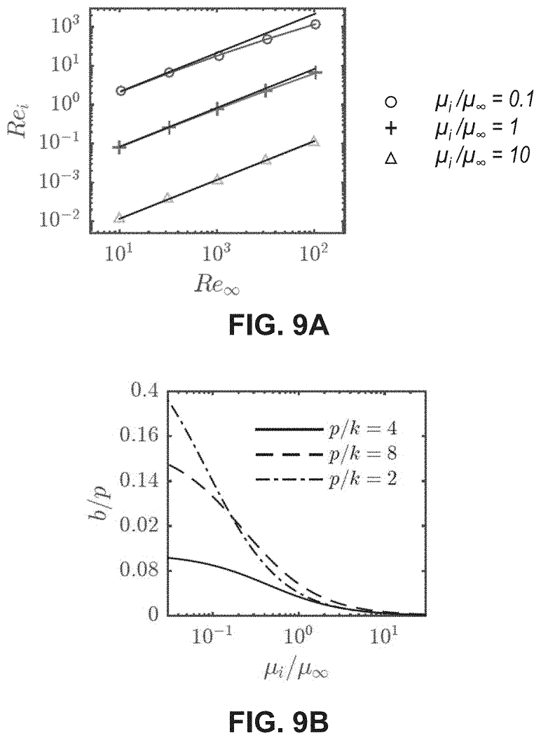

The relationships between Re_{∞} and Reᵢ obtained from the simulations are plotted in FIG. 9A. The slip velocity is related to the wall-normal derivative of U= [symbol] u [symbol] as Uₛ=bdU/dy|_{y=0}, where b is the slip length, and dU/dy is evaluated at the interface in the external fluid. Since U_{∞}=(h+b)dU/dy|_{y=0}, the Re_{∞}-to-Reᵢ relation is a function of b. Slip lengths have also been derived analytically in the Stokes limit (Re_{∞}→0), with the corresponding Re_{∞}-to-Reᵢ relations also shown in FIG. 9A. There is reasonable agreement between the Stokes flow results and the simulations up to moderate Reᵢ(16% difference for Reᵢ=19 with μᵢ/μ_{∞}=0.1). The analytical slip lengths are plotted in FIG. 9B for three different pitches.

q_{conv,d}/q can also be shown for other cavity widths and pitches. For p/k=4 and the same vertical wall thickness, there is a reasonable agreement to eq. (4.3). This texture corresponds to a solid fraction ϕₛ=¼. For p/k=4 and ϕₛ=½, it also holds. However, for ϕₛ=¾, the increase of q_{conv,d}/q with Peᵢ is slower. For p/k=8, the relation is valid for ϕₛ=⅛ and ϕₛ=½ but not for ϕₛ=¾. From these simulations, it is clear that eq. (4.3) holds at least in the interval 2≲p/k≲8 for ϕₛ≲½, 10¹<Peᵢ<10³, and κₛ=κᵢ=κ_{∞}.

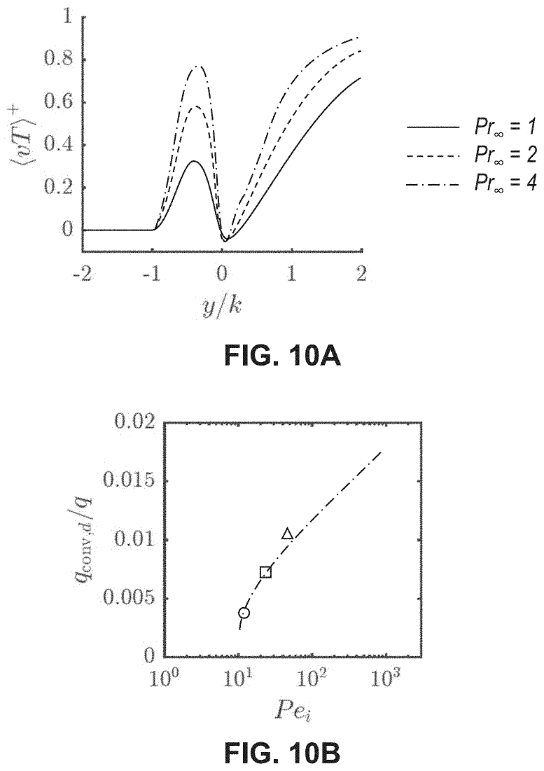

As indicated in eq. (4.3), it is assumed that q_{conv,d}/q is proportional to the ratio of the groove height to the domain height. The vertical size of the vortices in the grooves is approximately k (at least for 1≲w/k≲7). Therefore, the integral of [symbol] \tilde{v}\tilde{T} [symbol] scales with k. The definition of q_{conv,d} then results in the scaling with k/(h+2k) (eq. 2.4). This ratio is also an approximate upper limit of q_{conv,d}/q. Similar to what is shown in FIG. 10A, [symbol] \tilde{v}\tilde{T} [symbol] for p/k=4 is approximately zero above the grooves, so that

$$\frac{{q}_{conv , d}}{q} = \frac{1}{h + 2 k} {\int }_{- k}^{h} \frac{ρ {c}_{p} 〈 \tilde{v} \tilde{T} 〉}{q} d y \approx \frac{1}{h + 2 k} {\int }_{- k}^{0} \frac{ρ {c}_{p} 〈 \tilde{v} \tilde{T} 〉}{q} d y < \frac{k}{h + 2 k} \qquad ( 4.4 )$$

since ρcₚ [symbol] \tilde{v}\tilde{T} [symbol] <q holds if it is assumed that the temperature profile is strictly decreasing. The latter assumption has been seen to be violated locally for high Pr_{∞} but by a negligible amount. For the laminar simulations (h=2k), the limiting value is 25%.

Since the dispersive convection mainly is contained in the grooves, it is possible to quantify the heat transfer through the LIS by a surface Nusselt number. This example considers only the texture, equivalent to h=0, and define an average temperature at the interface, (the slip [symbol] temperature) Tₛ= [symbol] T [symbol] _{y=0}, and a temperature at the bottom of the texture, T_{bt}= [symbol] T [symbol] _{y=-k}. The surface Nusselt number becomes

$$N {u}_{s} = \frac{k q}{{κ}_{i} ( {T}_{b t} - {T}_{s} )} = \frac{1}{1 - \frac{{q}_{c o n v , d}}{q}} \qquad ( 4.5 )$$

The inequality in (4.4), applied to the texture only, limits Nuₛ to finite positive values.

Heat exchangers can be represented by thermal resistance circuits. The thermal resistances of the circuit components, proportional to the inverse of their Nusselt numbers, are then evaluated separately. These resistances can then be added to form the total thermal resistance of the system if they are in series. Hatte & Pitchumani (2021) constructed such a model to describe convective heat transfer in pipes with LIS, with the texture and the bulk as components. However, they implicitly neglected the dispersive convection by imposing Nuₛ=1. Since Nuₛ>1 with convection included, the resulting heat flux of the complete system is higher than their model predicts. In the upper limit of eq. (4.4) applied to the texture, Nuₛ→∞. Accordingly, the thermal resistance of the surface becomes zero. Eq. (4.5), together with eq. (4.3) to describe q_{conv,d}/q, could be used for a more precise evaluation of Nuₛ for the parameters and geometry considered in the disclosed systems.

Flow with Turbulence.

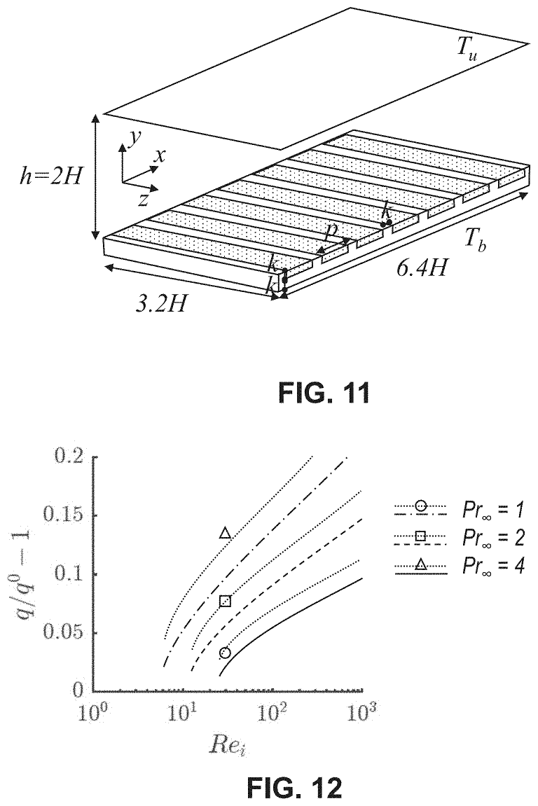

In turbulent flow, all the terms in eq. (2.4) contribute to the heat flux since the flow also contains random fluctuations. Simulations have been carried out for a turbulent channel flow with LIS with a finite difference method. The bulk Reynolds number was set to Re_{b}=ρU_{b}H/μ_{∞}=2800 (where H=h/2 is the channel half-height), resulting in a friction Reynolds number of Re_{τ}=ρu_{τ}H/μ_{∞}≈180, where U_{b} is the bulk velocity, and u_{τ} is the friction velocity. A constant mass flow rate was achieved by applying a uniform volume force in the infused and external liquids. The simulation domain is illustrated in FIG. 11. It had dimensions (Lₓ, L_{y}, L_{z})=(6.4H, 2H+2k, 3.2H), and the number of grid points was (Nₓ, i, N_{z})=(640, 384, 640) in the streamwise, wall-normal, and spanwise directions. The grid was stretched in the wall-normal direction but uniform in the streamwise and spanwise directions. The smallest wall-normal grid spacing was Δy⁺≈0.2, where a superscript+indicates wall units.

Transverse grooves were placed on one wall, with p/k=4, ϕₛ=¼, and k=0.05H (over −0.05H≤y≤0), on top of a slab of solid material with the same thickness (over −0.1H≤y≤0.05H). The groove height corresponds to k⁺≈9. Since the transverse grooves only were positioned on one wall, the friction velocity differed slightly between the bottom and upper surface. All wall units were based on the friction velocity of the bottom surface (with the grooves), computed from the balance between the applied volume force in the external flow and the wall-shear stress of the smooth upper wall. Similar to the laminar configuration, constant temperatures Tᵤ and T_{b} were imposed at the upper and the bottom boundaries, respectively. The viscosity ratio was set to μᵢ/μ_{∞}=0.4, corresponding roughly to heptane-water (see Table 1). The solid thermal conductivity was κₛ=κᵢ. Three simulations were performed with Prandtl numbers Pr_{∞}=1, 2, and 4, respectively. These simulations were also conducted with smooth walls, replacing the grooves with solid material. For more information about the code and grid sensitivity studies, see Ciri, U. & Leonardi, S. 2021 Heat transfer in a turbulent channel flow with super-hydrophobic or liquid-infused walls. J. of Fluid Mech. 908, A28 (the contents of which are incorporated by reference herein in their entirety), where the same code was used with a similar setup.

These groove dimensions give a slight drag reduction for turbulent flow compared to a smooth wall. It was computed to

$$D R = \frac{{τ}^{0} - τ}{{τ}^{0}} = 0.028 \qquad ( 5.1 )$$

where τ is the total drag of the bottom surface, and τ⁰ is the wall-shear stress from the reference simulation with smooth walls. The results from the turbulent simulations are summarized in Table 2, below.

Table 2. Summary of results from the turbulent simulations. The friction Reynolds number of the smooth channel flow was Re_{τ}⁰=178.7, and for the flow with LIS, Re_{τ}⁰=176.1, based on the friction velocity of the textured surface. The quantities τ⁰, q⁰, and Nu⁰ are wall-shear stress, heat flux and Nusselt number of the smooth wall simulations, respectively.

| Pr_{∞} | DR (%) | (q-q⁰)/q (%) | Nu⁰ | ϵ · 10³ | q_{conv, d}/ q · 10³ | $\frac{q}{{q}_{0}} \frac{{τ}_{0}}{τ}$ |
|---|---|---|---|---|---|---|
| 1 | 2.8 | 3.3 | 5.8 | 1.7 | 3.8 | 1.06 |
| 2 | 2.8 | 7.8 | 7.5 | 2.3 | 7.3 | 1.11 |
| 4 | 2.8 | 13.6 | 9.3 | 2.4 | 10.5 | 1.17 |

FIG. 10A shows

$$\frac{ρ {c}_{p} 〈 \tilde{v} \tilde{T} 〉}{q} = {〈 \tilde{v} \tilde{T} 〉}^{+}$$

from turbulent and laminar simulations for the same Reynolds number Reᵢ=29.4. There is a relatively good agreement between the two setups. The difference is the largest for the lowest Prandtl number; the laminar result slightly under-predicts the turbulent [symbol] \tilde{v}\tilde{T} [symbol] ⁺ (by 13% at the peak if normalized with the latter, corresponding to an absolute difference of 0.041). For Pr_{∞}=2 and 4, the differences in the peak values were 3% and 4%, respectively. These differences are considered small enough to use the laminar results to interpret the turbulence simulations. Earlier studies indicate that dispersive quantities of rough-wall flow can be reproduced by laminar flow if the offset of the mean velocity in the logarithmic region compared to smooth-wall flow is small (ΔU⁺≲2). Correspondence between the laminar and turbulent results of [symbol] \tilde{v}\tilde{T} [symbol] is therefore expected here. In FIG. 10B, q_{conv,d}/q is compared to eq. (4.3). The upper limit of q_{conv,d}/q for the turbulent flow setup is 2.4% (eq. 4.4), which is much smaller than for the laminar. For a corresponding symmetric channel, the upper limit would be 4.5%. The contribution from q_{conv,d}/q is, therefore, somewhat restricted for this setup. Nevertheless, the total increase of the heat flux compared to the smooth-wall flow, q/q₀, was 3.3%, 7.8%, and 14% for Pr_{∞}=1, 2, and 4, respectively. See Table 2. For all these cases, the increase in q_{conv,r}/q₀ dominates the change in the heat flux. However, the main reason behind the enhancement of q_{conv,r}/q₀ is the finite value of q_{conv,d}/q, shown below.

FIG. 10A indicates only minor changes in [symbol] v′T′ [symbol] ⁺ compared to the smooth-wall flow. The difference in q_{conv,r}/q is introduced between the flow over the LIS and in the smooth channel,

$$ϵ = \frac{{q}_{c onv , r}}{q} - \frac{{q}_{c onv , r}^{0}}{{q}^{0}} \qquad ( 5.2 )$$

Rearranging eq. (2.4), an expression for the change in heat flux is

$$\frac{q}{{q}^{0}} = \frac{1}{1 - {Nu}^{0} ( \frac{{q}_{c o n v , d}}{q} + ϵ )} = \frac{1}{1 - {Nu}^{0} ( \frac{{q}_{c o n v , d}}{q} )} + O ( ϵ ) = \frac{1}{1 - \frac{{q}^{0} k}{{κ}_{∞} ( {T}_{b} - {T}_{u} )} 0.11 ln ( {Pe}_{i} - 7.6 )} + O ( ϵ ) \qquad ( 5.3 )$$

where Nu⁰ is defined as

$$N {u}^{0} = \frac{( h + 2 k ) {q}^{0}}{{κ}_{∞} ( {T}_{b} - {T}_{u} )} \qquad ( 5.4 )$$

Eq. (4.3) has been used in the latter form of the expression, applicable if 10¹<Peᵢ<10³. The Nusselt number Nu⁰ (or q⁰) depends on Pr_{∞} and Re_{τ} but can be known without performing simulations of LIS since it is a result of the smooth-wall flow. The other input parameter, Reᵢ, can be computed or estimated as in FIGS. 9A-9B. Therefore, if E is neglected, eq. (5.3) predicts the heat flux of the LIS.

For laminar flow over smooth walls, Nu⁰=1. If there are random fluctuations in the flow,

$$N {u}^{0} = \frac{{q}^{0}}{{q}_{c o n d}^{0}} = \frac{{q}_{c onv , r}^{0}}{{q}_{c o n d}^{0}} + 1 ,$$

demonstrating how Nu⁰ increases due to convection. Values measured from the simulations with smooth walls were Nu⁰=5.8, 7.5, and 9.3 for Pr_{∞}=1, 2, and 4, respectively. See Table 2. For flow over LIS assuming E=0, the ratio of the random convection to the total heat flux, q_{conv,r}/q, does not change compared to the smooth-wall flow (eq. 5.2). Accordingly, q_{conv,r}/q⁰ changes proportionally to q/q⁰. The conduction does not change with q/q⁰ because g_{cond}=g_{cond}⁰. The total heat flux increases when the solid wall is replaced with a LIS, i.e., q/q⁰>1, hence q_{conv,r}/q⁰ increases but not q_{cond}/q⁰. Since the heat transfer enhancement is (g_{conv,r}+g_{conv,d}+g_{cond})/q⁰, it is more significant than what only g_{conv,d} would produce with g_{conv,r}=q_{conv,r}=0 (i.e., at Nu⁰=1). Indeed, this amplification is substantial, as seen from the values of Nu⁰. This effect can be expected to increase with increasing bulk Reynolds or Prandtl numbers; previous work has shown Nu⁰ increases linearly with Re_{τ} for a channel with smooth isothermal walls.

Eq. (5.3) is shown in FIG. 12, both for E=0 and 2.3·10⁻³. The latter corresponds to the measured value for Pr_{∞}=2. For Pr_{∞}=1, E was somewhat lower, and for Pr_{∞}=4 slightly higher (see Table 2). The positive values of E further enhance the heat flux, which is seen from the first form of the expression in eq. (5.3). This expression with E=0 is a lower limit of q/q⁰. Since the sum of E and g_{conv,d}/q enters the equation, their magnitudes can be compared: q_{conv,d}/q is 2.2, 3.1, and 4.4 times larger for Pr_{∞}=1, 2, and 4, respectively.

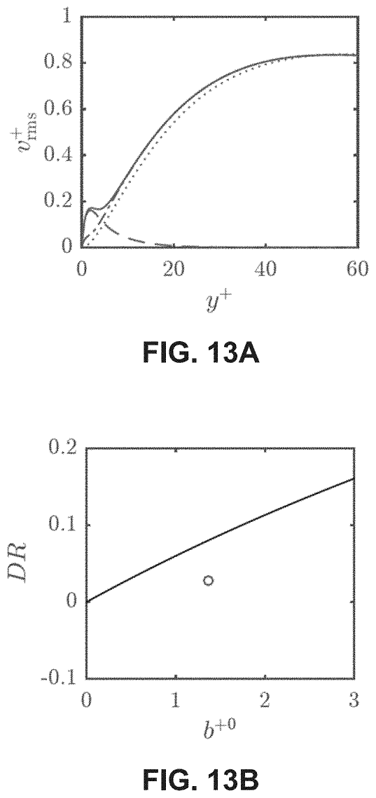

The slight increase of [symbol] v′T′ [symbol] ⁺, is reflected by the wall-normal velocity fluctuations. The root-mean-squared value, vᵣₘₛ⁺, is not reduced due to the presence of the interface but instead increases near the surface (see FIG. 13A). It is the varying slip-no slip condition at y=0, acting like roughness, that causes this. The increase of vᵣₘₛ⁺, also amplifies the production of [symbol] vT [symbol] ⁺ above the surface. The effects from the change in the turbulence on DR are known to be generally severe for transverse grooves. The current DR and the ideal drag reduction relationship by Rastegari & Akhavan (2015) are shown in FIG. 13B. This relationship was derived for channels with symmetric walls but can also be applied to asymmetric configurations if DR is computed by eq. (5.1). Without roughness effects, it predicts that the drag reduction would be 8%. Nevertheless, this example achieves DR>0 together with a heat transfer increase for this geometry.

The heat transfer efficiency of the system can be measured by the heat flux to drag ratio or, equally, the Reynolds analogy factor, 2St/C_{f}, where St is the Stanton number and C_{f} is the friction coefficient. According to the Reynolds analogy, 2St/C_{f}=1 for flow over smooth walls with Pr_{∞}=1. Changes in the heat flux to drag ratio when introducing surface modifications at this Prandtl number thus indicate a breakage of the Reynolds analogy. A growth or a reduction equal increased or decreased heat transfer efficiency, respectively. However, the exact value of 2St/C_{f} for smooth-wall flows depends on the normalization used to form the non-dimensional numbers. The heat flux to drag ratio normalized with the smooth wall reference values, (q/q₀)(τ₀/τ), is a valid measure of the heat transfer efficiency independently of the Prandtl number. This quantity is reported in Table 2. Since both q/q₀>1 and τ₀/τ>1 for the current setup, (q/q₀)(τ₀/τ) exceeds unity, having a maximum value of 1.17 for Pr_{∞}=4. For LIS and SHS with isothermal solids, it ranges between 0.9 and 1.2.

Thus, the presently disclosed system can simultaneously regulate heat transfer and fluid friction. Heretofore, surfaces were designed to regulate only one of these functions.

Current technology for increasing heat transfer is based on modulating surfaces with large grooves, fins, blades, corrugations, or other physical contraptions. This results in increased surface area and intensification of turbulence (thus convection). A weakness is the increased drag force from these modulations. Thus, conventional techniques include surfaces that is designed to increase heat transfer, but result in increased fluid friction, and thus requires higher energy input (for example the pumping power needed to operate a heat exchanger). The disclosed approach is a design that increases heat transfer without increasing fluid friction, or with only minimal increase. The approach disclosed herein infuses (or lubricates, impregnates) the surface with a liquid that is held in place by grooves or cavities. If the appropriate liquid is infused, the heat transfer can be increased without an increased drag, or with only a minimal increase in drag.

Steps for the disclosed approach comprise:

1. The liquid-infused surface is made by creating grooves or cavities of (for example) rectangular shape in a solid surface composed of an appropriate material (polymer, semiconductor, dielectric, steel, etc.).

2. The grooves in the surface are then filled with an appropriate infused liquid (alkane, liquid metal, etc.). The grooves contain, conduct and convect heat to the infused liquid. The infused liquid is used to increase heat transfer from the solid to the working fluid, without increasing the drag from the working fluid on the surface, or only minimally increasing the drag.

3. The surface is submerged in an appropriate working fluid (water, etc.) that flows parallel to the surface.

Various modifications may be made to the systems, methods, apparatus, mechanisms, techniques and portions thereof described herein with respect to the various figures, such modifications being contemplated as being within the scope of the invention. For example, while a specific order of steps or arrangement of functional elements is presented in the various embodiments described herein, various other orders/arrangements of steps or functional elements may be utilized within the context of the various embodiments. Further, while modifications to embodiments may be discussed individually, various embodiments may use multiple modifications contemporaneously or in sequence, compound modifications and the like.

Although various embodiments which incorporate the teachings of the present invention have been shown and described in detail herein, those skilled in the art can readily devise many other varied embodiments that still incorporate these teachings. Thus, while the foregoing is directed to various embodiments of the present invention, other and further embodiments of the invention may be devised without departing from the basic scope thereof. As such, the appropriate scope of the invention is to be determined according to the claims.

What is claimed:

1. A system for increasing heat transfer from a substrate to a working fluid, comprising:
a substrate comprising a plurality of grooves or cavities on at least one external surface;
an infusing liquid filling at least a majority of the plurality of grooves;
a working fluid configured to flow parallel to the external surface.

2. The system according to claim 1, wherein the plurality of grooves consists of micro- and/or nano-scale grooves.

3. The system according to claim 1, wherein each of the plurality of grooves is a rectangular groove.

4. The system according to any claim 1, wherein each of the plurality of grooves are oriented in a first direction on the at least one external surface.

5. The system according to claim 4, wherein the working fluid is configured to flow in a second direction, the second direction being perpendicular to the first direction.

6. The system according to claim 1, wherein each of the plurality of grooves are oriented in a seemingly random fashion on the at least one external surface.

7. The system according to claim 1, wherein the substrate is comprised of a polymer, metal, dielectric, or metal.

8. The system according to claim 1, wherein the infusing liquid is comprised of a hydrocarbon or a liquid metal.

9. The system according to claim 8, wherein the hydrocarbon is an alkane.

10. The system according to claim 9, wherein a carbon chain of the alkane is 6-18 carbons in length.

11. The system according to claim 1, wherein the working fluid comprises water.

12. The system according to claim 1, further comprising a processor, sensor, or circuitry in thermal communication with the infusing liquid.

13. A method for providing increased heat transfer with minimal increase in frictional losses, comprising:
flowing a working fluid parallel to an external surface of a substrate, the external surface comprising a plurality of grooves or cavities and an infusing liquid filling at least a majority of the plurality of grooves or cavities, such that the working fluid thermally communicates with the infusing liquid and the plurality of grooves.

14. The method according to claim 13, wherein the plurality of grooves consists of micro and/or nano-scale grooves.

15. The method according to claim 13, wherein each of the plurality of grooves are oriented in a first direction on the at least one external surface.

16. The method according to claim 15, wherein the working fluid is configured to flow in a second direction, the second direction being perpendicular to the first direction.

17. The method according to claim 13, wherein the substrate is comprised of a polymer, metal, dielectric, or metal.

18. The method according to claim 13, wherein the infusing liquid is comprised of a hydrocarbon or a liquid metal.

19. The method according to claim 13, wherein the working fluid comprises water.

20. The method according to claim 13, further comprising controlling flow of the working fluid based on a measured temperature.
